(19) United States
(12) Patent Application Publication
(10) Pub. No.: US 2009/0020228 A1
(43) Pub. Date: Jan. 22, 2009

(54) PLASMA PROCESSING APPARATUS AND PLASMA GENERATION CHAMBER

(75) Inventor: Daisuke HAYASHI, Yamanashi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 12/174,062

(22) Filed: Jul. 16, 2008

Related U.S. Application Data
(60) Provisional application No. 60/982,750, filed on Oct. 26, 2007.

(30) Foreign Application Priority Data
Jul. 18, 2007 (JP) 2007-187262

(51) Int. Cl. H01L 21/306

(52) U.S. Cl. 156/345.48

(57) ABSTRACT

A plasma processing apparatus comprises a processing chamber having installed therein a stage upon which a wafer W is placed and a plasma generation chamber communicating with the processing chamber. The plasma generation chamber includes a reaction container having a tubular side wall, a coil wound around the side wall, to which a specific level of high-frequency power is applied, and a film coating covering the outer surface of the side wall. The film coating is a thin film that blocks ultraviolet light originating from the plasma generated inside the reaction container and is constituted of an insulating material with a heat resisting property.

### CROSS-REFERENCE TO RELATED APPLICATIONS

This document claims priority to Japanese Patent Application Number 2007-187262, filed on Jul. 18, 2007 and U.S. Provisional Application No. 60/982,750, filed on Oct. 26, 2007, the entire content of which are hereby incorporated by reference.

### FIELD OF THE INVENTION

The present invention relates to a plasma processing apparatus that executes a specific type of processing on a processing target substrate with plasma generated by exciting a processing gas and it also relates to a plasma generation chamber.

### BACKGROUND OF THE INVENTION

During a manufacturing process for manufacturing, for instance, semiconductor devices, a specific film formed on a processing target substrate such as a semiconductor wafer (hereafter may be simply referred to as a “wafer”) is selectively etched and removed by using a resist film formed at the surface of the wafer as a mask thereby forming contact holes or the like, and then the resist film is removed through ashing. In addition, before film formation processing is executed to form a film at the contact holes or the like, the natural oxide base film present inside the holes may be removed. Such an ashing process or a natural oxide film removal process is often executed with oxygen-containing plasma generated by exciting an oxygen-containing gas in the related art.

A plasma processing apparatus that processes wafers with oxygen-containing plasma as described above in the known art may comprise a processing chamber equipped with a stage on which a wafer is held and a substantially cylindrical bell jar constituting a plasma generation chamber disposed continuously to the processing chamber atop the processing chamber, where oxygen-containing plasma is generated by exciting a processing gas containing oxygen (see, for instance, patent reference literature 1 listed below). The bell jar is constituted of an insulating material such as quartz glass and a coil used as an antenna member to connect with a high-frequency power source is wound around the side wall of the bell jar. As the oxygen-containing processing gas is supplied into the bell jar and high-frequency power is supplied to the coil in the plasma processing apparatus structured as described above, the bell jar side wall and the coil together function as part of a high-frequency (RF) circuit and oxygen-containing plasma is generated by forming an induction field inside the bell jar. The natural oxide film, having settled onto the surface of the wafer, for instance, can then be removed with the oxygen-containing plasma thus generated.

As semiconductor elements today need to assume a multilayer structure with a greater number of wiring layers stacked one on top of another, a low dielectric constant film with a low dielectric constant, such as a low-k film, is frequently used as an insulating film in the multilayer wiring structure. Since such a low dielectric constant insulating film is readily damaged by oxygen-containing plasma, hydrogen-containing plasma with which damage can be more successfully inhibited is utilized when processing a wafer with a low dielectric constant insulating film formed thereupon (when etching, ashing, executing natural oxide film removal processing or the like). (See, for instance, patent reference literature 2 listed below)

Intense ultraviolet light may be generated from plasma generated by exciting a certain type of processing gas supplied into the bell jar. For instance, it has been learned that more intense ultraviolet light is generated from plasma generated by exciting a hydrogen-containing processing gas than plasma generated by exciting an oxygen-containing processing gas.

In a plasma generation chamber such as the bell jar described above, where plasma is generated with an induction field generated by applying high-frequency power to the coil wound around the side wall thereof, the side wall of the plasma generation chamber forms part of the high-frequency circuit through which the induction field is generated. Accordingly, the side wall is normally constituted of an insulating material such as quartz glass. However, light with a small wavelength such as ultraviolet light tends to be transmitted readily through an insulating material such as quartz glass and thus, there arises a concern that as hydrogen-containing plasma is generated inside the side wall constituted of quartz glass or the like, the intense ultraviolet light generated from the plasma may be readily transmitted through the side wall and leaked to the outside.

A plasma generation chamber may be formed with thick quartz glass or the like to constitute the side wall thereof so as to ensure that the ultraviolet light is dissipated inside the quartz glass enclosure instead of leaking to the outside of the plasma generation chamber. However, the induction field can be generated with better efficiency when the side wall of the plasma generation chamber assumes a smaller thickness and a thinner side wall is less likely to break. Thus, there is a dilemma that must be worked out in that while it is more desirable to form the plasma generation chamber with a thinner side wall from the viewpoint of the induction field generation efficiency, ultraviolet light is allowed to leak to the outside more readily through a thin side wall.

The ultraviolet light having been transmitted through the side wall and leaked out into the atmosphere outside the side wall is bound to react with oxygen in the atmosphere, producing ozone. Since a greater quantity of ozone will be produced as the quantity of ultraviolet light leaked to the outside of the plasma generation chamber increases, effective countermeasures need to be taken.

The microwave plasma processing apparatus disclosed in patent reference literature 3 listed below includes an ultraviolet light shield plate disposed above the microwave intake window so as to prevent ultraviolet light from being transmitted through the microwave intake window and leaking to the outside.

However, the side wall of the plasma generation chamber constituted with the bell jar described above, unlike the microwave intake window in patent reference literature 3, constitutes, together with the coil wound around the side wall, part of the high-frequency circuit via which the induction field used to excite the processing gas into plasma is formed. This means that if a plate member to be used to simply block ultraviolet light is installed between the side wall and the coil, the capacitance and the like of the high-frequency circuit will be altered depending upon the material constituting the plate member, the thickness of the plate member, the plate member installation arrangement and the like, and under certain circumstances, a desired induction field may not be generated. Such a failure to generate the specific induction field will alter the state of plasma generated inside the plasma generation chamber, which, in turn, may affect the wafer processing results.

While the ultraviolet light may be blocked simply by increasing the thickness of the side wall of the plasma generation chamber or using a specific material for the side wall, such an alteration in the material constituting the side wall or in the shape of the side wall forming part of the high-frequency circuit is bound to affect the capacitance or the like of the high-frequency circuit, which may result in a failure in generating the desired induction field in some cases.

In addition, the ultraviolet blocking member, to be installed between the side wall and the coil forming part of the high-frequency circuit, needs to be constituted of an insulating material, since if the blocking member were constituted of an electrically conductive material, problems such as shorting in the high-frequency circuit would occur. If there is an air gap between the side wall and the ultraviolet light blocking member, ozone may be produced and for this reason, the ultraviolet light blocking member must be installed in close contact with the side wall without any gap. However, the temperature on the outer side of the side wall rises to a higher level (e.g., 400° C. or higher) as a higher level of high-frequency power is supplied to the coil increases and, accordingly, the material constituting the ultraviolet light blocking member must assure a high level of heat resisting performance in order to withstand the high temperature. In short, various restrictions apply to the ultraviolet blocking member installed between the side wall and the coil constituting part of the high-frequency circuit and the material used to constitute the ultraviolet blocking member must satisfy the various requirements.
(patent reference literature 1) Japanese Laid Open Patent Publication No. 2004-158828
(patent reference literature 2) Japanese Laid Open Patent Publication No. 2006-073722
(patent reference literature 3) Japanese Laid Open Patent Publication No. H07-254499

### SUMMARY OF THE INVENTION

Accordingly, an object of the present invention, having been completed by addressing the issues discussed above, is to provide a plasma processing apparatus that does not allow ultraviolet light generated from plasma to leak to the outside, without affecting the induction field generated inside a plasma generation chamber.

The object described above is achieved in an aspect of the present invention by providing a plasma processing apparatus that executes a specific type of processing on a processing target substrate with plasma generated by exciting a hydrogen-containing processing gas, comprising a plasma generation chamber where plasma is generated by exciting the processing gas, a processing chamber communicating with the plasma generation chamber and a stage disposed inside the processing chamber, upon which the processing target substrate is placed. The plasma generation chamber in the plasma processing apparatus includes a reaction container having a tubular side wall, a processing gas delivery unit through which the processing gas is delivered into the reaction container, a coil wound around the side wall, to which specific high-frequency power is applied and a film coating that covers the outer surface of the side wall. The film coating is a thin film constituted of an insulating material with a heat resisting property, which blocks ultraviolet light generated from the plasma generated inside the reaction container.

The object described above is also achieved in another aspect of the present invention by providing a plasma generation chamber where plasma is generated by exciting a hydrogen-containing processing gas, comprising a processing gas intake portion via which the processing gas is taken in, a reaction container having a tubular side wall, a processing gas delivery unit through which the processing gas is delivered into the reaction container, a coil wound around the side wall, to which specific high-frequency power is applied and a film coating that covers the outer surface of the side wall. The film coating is a thin film constituted of an insulating material with a heat resisting property, which blocks ultraviolet light generated from the plasma generated inside the reaction container.

According to the present invention described above, with the outer surface of the side wall of the reaction container constituting the plasma generation chamber coated with a film coating that blocks ultraviolet light, the ultraviolet light generated from the plasma formed inside the reaction container is not allowed to leak out into the atmosphere outside the side wall and, as a result, production of ozone through a reaction of the ultraviolet light and the oxygen in the atmosphere is effectively prevented.

In addition, the film coating is a thin film constituted of an insulating material with a heat resistant property and thus, its presence between the side wall and coil constituting part of the high-frequency circuit via which the induction field to be used to excite the processing gas into the plasma state is formed inside the plasma generation chamber, does not compromise the function of the high-frequency circuit. As a result, the desired induction field can be generated inside the plasma generation chamber and leakage of the ultraviolet light generated from the plasma is effectively prevented without affecting the state of the plasma generated inside the plasma generation chamber. Namely, since the film coating is constituted of an insulating material instead of an electrically conductive material, no shorting occurs at the high-frequency circuit even as high-frequency power is applied to the coil. Furthermore, since the film coating constituted with a thin film blocks ultraviolet light, the need to increase the thickness of the side wall is eliminated and thus, the capacitance and the like of the high-frequency circuit are not affected. Moreover, since the side wall and the film coating are set in close contact with each other, ozone is not produced between the side wall and the film coating.

In addition, the film coating with its heat resisting property will withstand high heat even when it is formed in close contact with the side wall of the reaction container, the temperature of which rises as plasma is generated. In practical application, the film coating should assure heat resisting performance to withstand temperatures of 400° C. and higher. Such a film coating can be utilized successfully in various types of processing that the processing target substrate may undergo.

The inner surface and the outer surface of the side wall of the reaction container may be roughened and the film coating may be formed at the outer surface having undergone the roughening treatment. In such as case, rays of light including the ultraviolet light generated from the plasma will be reflected irregularly both at the inner surface and the outer surface of the side wall and thus will not be allowed to concentrate over any specific area of the side wall. Since the film coating is formed at the outer surface of the side wall having undergone the roughening treatment, better contact will be achieved for the side wall and the film coating and thus, the film coating will not readily crack.

The inner surface and the outer surface of the side wall of the reaction container may be roughened over their entirety, or only the outer surface of the side wall of the reaction container may be roughened over its entirety with the inner surface of the side wall roughened only in part.

It is to be noted that when partially roughening the inner surface of the side wall of the reaction container, an area of the inner surface surrounding plasma generated inside the reaction container may be roughened in correspondence to the plasma generation position. Through these measures, an area of the inner surface of the side wall where intense light including the ultraviolet light generated from the plasma is likely to concentrate to crack the film coating, will be roughened to irregularly reflect the light. In this case, the area of the inner surface of the side wall to undergo the roughening treatment is minimized while assuring full prevention of film coating cracking. Consequently, particles and the like of reaction product becoming adhered onto the inner surface of the side wall can be minimized.

The object described above is achieved in an yet another aspect of the present invention by providing a plasma processing apparatus that executes a specific type of processing on a processing target substrate with plasma generated by exciting a hydrogen-containing processing gas, comprising a plasma generation chamber where plasma is generated by exciting the processing gas, a processing chamber communicating with the plasma generation chamber and a stage disposed inside the processing chamber, upon which the processing target substrate is placed. The plasma generation chamber in the plasma processing apparatus includes a reaction container having a side wall formed as an integrated member by layering a plurality of tubular members constituted of an insulating material with a vacuum sealed space set therebetween, a processing gas delivery unit through which the processing gas is delivered into the reaction container, a coil wound around the side wall, to which specific high-frequency power is applied and a film coating that covers the outer surface of the side wall. The film coating is a thin-film constituted of an insulating material with a heat resisting property, which blocks ultraviolet light generated from the plasma generated inside the reaction container.

According to the present invention described above, the ultraviolet light generated from the plasma generated in the reaction container is not allowed to leak into the atmosphere outside the side wall and thus ozone is not readily generated through the reaction of the ultraviolet light and the oxygen present in the atmosphere. Furthermore, since the side wall of the reaction container adopts a multiple layer structure with a plurality of tubular members layered one on top of another, the temperature at the outer surface of the side wall can be kept down even as plasma is generated inside the reaction container, which ultimately prevents cracking of the film coating due to deterioration in its strength.

The inner surfaces and the outer surfaces of the individual tubular members may be roughened, and the film coating may be formed at the outer surface of the outermost tubular member having undergone the roughening treatment. Through these measures, light including the ultraviolet light generated from the plasma P is effectively prevented from concentrating over any specific area of the side wall and thus, cracking of the film coating is even more effectively prevented.

The inventor of the present invention et al. confirmed through trial and error, that ideal materials that may be used to form the film coating include a silica-containing amorphous carbon film material. The silica-containing amorphous carbon film material is an ultraviolet light-blocking material that does not allow light with wavelengths equal to and less than 300 nm, such as ultraviolet light, to be transmitted through. It also has an insulating property and assures a high level of heat resisting property that allows it to withstand high temperatures of 500° C. and higher. Furthermore, a thin film constituted of such a silica-containing amorphous carbon film material can be formed at the side wall through CVD so that the film coating is formed with close contact, without any gap, onto the outer surface of the side wall.

It is to be noted that the description in the specification is provided by assuming that 1 Torr=(101325/760) Pa.

The present invention provides a plasma processing apparatus and the like, with which leakage of ultraviolet light, originating from plasma generated inside the plasma generation chamber, to the outside of the plasma generation chamber is effectively prevented without affecting the state of the plasma.

### BRIEF DESCRIPTION OF THE DRAWINGS

FIG. 1 is a sectional view presenting an example of a structure that may be adopted in the plasma processing apparatus achieved in an embodiment of the present invention;

FIG. 2 schematically illustrates how ultraviolet light originating from plasma generated inside the side wall of the reaction container shown in FIG. 1 may be blocked;

FIG. 3 presents a diagram of the spectrum of light measured outside the side wall of the reaction container, provided to facilitate comparison of the spectrum measured with a film coating formed at the side wall (film coating present) and the spectrum of the light measured without forming a film coating at the side wall (film coating absent);

FIG. 4 schematically illustrates how the film coating in the embodiment may become cracked due to deterioration in the film quality;

FIG. 5 schematically illustrates variation of the embodiment achieved by roughening the inner surface and the outer surface of the side wall of the reaction container;

FIG. 6 schematically illustrates how ultraviolet light originating from plasma generated inside the side wall of the reaction container shown in FIG. 5 may be blocked;

FIG. 7 schematically illustrates another variation of the embodiment with the side wall of the reaction container assuming a double-layer structure achieved by layering two tubular members; and

FIG. 8 schematically illustrates the tubular members constituting the side wall of the reaction container in FIG. 7 with the inner surfaces and the outer surfaces thereof roughened.

### DETAILED DESCRIPTION OF THE PREFERRED EMBODIMENT

The following is a detailed explanation of the preferred embodiment of the present invention, given in reference to the attached drawings. It is to be noted that in the description and the drawings, the same reference numerals are assigned to components having substantially identical functions and structural features to preclude the necessity for a repeated explanation thereof.

### (Structural Example For the Plasma Processing Apparatus)

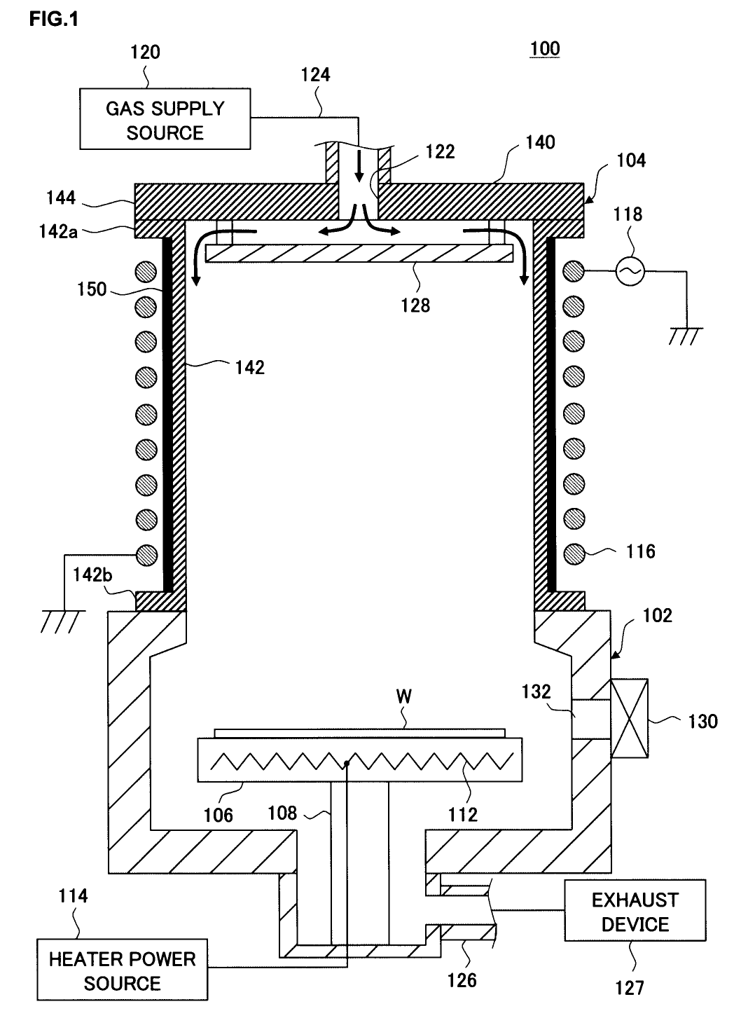

First, in reference to a drawing, a structural example that may be adopted in the plasma processing apparatus achieved in an embodiment of the present invention is explained. The following explanation is provided by assuming that the present invention is adopted in a down-flow type plasma processing apparatus that processes substrates by using hydrogen radicals generated from plasma (hereafter may be referred to as “hydrogen plasma”) raised from a hydrogen-containing processing gas. FIG. 1 is a longitudinal sectional view schematically illustrating the structure of the plasma processing apparatus 100 achieved in the embodiment. In the plasma processing apparatus 100, a photoresist film formed upon a low dielectric constant insulating film with a lower dielectric constant, such as a low-k film, is removed through ashing by supplying hydrogen radicals over to a wafer W having the lower dielectric constant insulating film formed thereupon.

As shown in FIG. 1, the plasma processing apparatus 100 includes a processing chamber 102 where the wafer W is processed and a plasma generation chamber 104 communicating with the processing chamber 102 and assuming a substantially cylindrical shape, where plasma is generated by exciting a processing gas. The plasma generation chamber 104, disposed continuously to and above the processing chamber 102, is structured so that plasma is generated through an inductively coupled plasma method from the processing gas delivered therein.

A disk-shaped stage 106, upon which the wafer W can be supported levelly, is disposed inside the processing chamber 102. The stage 106 is supported by a cylindrical support member 108 disposed at the bottom of the processing chamber 102. The stage 106 is constituted of ceramic such as aluminum nitride. It is to be noted that a clamp ring (not shown), which clamps the wafer W placed on the stage 106, may be disposed at the outer edge of the stage 106.

In addition, a heater 112 that heats the wafer W is installed within the stage 106. As power is supplied to the heater 112 from a heater power source 114, the heater 112 heats the wafer W to a predetermined temperature (e.g., 300° C.). It is desirable that the predetermined temperature be set within a relatively high temperature range of, for instance, 250° C.˜400° C., over which the low dielectric constant insulating film remains substantially undamaged.

An exhaust pipe 126 is connected to the bottom wall of the processing chamber 102 and an exhaust device 128, which includes a vacuum pump, is connected to the exhaust pipe 126. As the exhaust device 127 is engaged in operation, the pressure in the processing chamber 102 and the plasma generation chamber 104 can be lowered to achieve a predetermined degree of vacuum.

At the side wall of the processing chamber 102, a transfer port 132 that can be opened/closed via a gate valve 130 is formed. The wafer W is carried into/out of the processing chamber via a transfer mechanism such as a transfer arm (not shown).

The plasma generation chamber 104 includes a reaction container 140 constituted with a tubular side wall 142 with open ends at the top and the bottom thereof and a lid member 144 that closes off the upper open end of the side wall 142 with a high level of airtightness. The side wall 142 is mounted at its bottom-side open end, to the open end formed on the top side of the processing chamber 102, so as to allow the inner space at the plasma generation chamber 104 to range continuously to the inner space at the processing chamber 102. The side wall 142 is detachably attached to the processing chamber 102 as, for instance, a lower flange 142b disposed at the bottom-side open end of the side wall is fixed onto the processing chamber 102 via a fastening member such as a bolt, as shown in FIG. 1.

The lid member 144 is detachably attached to an upper flange 142a disposed at the upper open end of the side wall 142 via a fastening member such as a bolt, as shown in FIG. 1. The processing gas delivery unit is connected to the lid member 144. More specifically, a gas delivery port 122 is formed at the lid member 144 and a specific type of processing gas originating from a gas supply source 120 is delivered into the reaction container 140 via the gas delivery port 122. Although not shown, a switching valve via which a gas piping 120 is open/closed, a mass flow controller that controls the flow rate of processing gas and the like are disposed at a gas piping 124 connecting the gas supply source 120 to the gas delivery port 122.

A rectifier plate 128 that regulates the flow of the processing gas delivered through the gas delivery port 122 is disposed at the lid member 144. In more specific terms, the rectifier plate 128 is mounted over a distance from the lower surface of the lid member 144, as shown in FIG. 1. As a result, the processing gas passing through the gas delivery port 122 is radially dispersed via the rectifier plate 128 from the vicinity of the center within the horizontal plane of the reaction container 140 toward the outer edges of the horizontal plane, allowing the processing gas to flow downward through the clearance between the rectifier plate 128 and the side wall 142. Thus, when generating, for instance, plasma assuming a toroidal shape achieving higher density around the edges of the horizontal plane than over the central area of the horizontal plane inside the reaction container 140, the processing gas can be supplied in greater quantity toward the peripheral area rather than toward the central area in the reaction container 140. This, in turn, minimizes waste of the processing gas and makes it possible to generate plasma efficiently. It is to be noted that the installation of the rectifier plate 128 is not essential and the plasma may be formed in a shape other than a toroid inside the reaction container 140.

The processing gas is a hydrogen-containing gas with which hydrogen radicals (H*) can be generated. Such a processing gas may be constituted with hydrogen gas alone or it may be a mixed gas containing hydrogen gas and an inert gas. The inert gas in the mixed gas may be, for instance, helium gas, argon gas or neon gas. It is to be noted that when a mixed gas containing hydrogen gas and an inert gas is used as the processing gas, the hydrogen gas should be mixed with a mixing ratio of, for instance, 4%.

The side wall 142 of the reaction container 140 is constituted of an insulating material such as quartz glass or ceramic and a coil 116 to function as an antenna member is wound around the outer circumference of the side wall 142. A high-frequency power source 118 is connected to the coil 116. The high-frequency power source 118 is capable of outputting high-frequency power with a predetermined power level in a range of 300 kHz through 60 MHz. A plurality of plasma formations can be generated along the height of the reaction container 140 in correspondence to the frequency (resonance mode) of the high-frequency power supplied to the coil 116. For instance, three toroidal plasma formations, set apart from each other along the height of the reaction container 140, may be formed.

An induction field is formed inside the reaction container 140, i.e., inside the side wall 142, in the plasma generation chamber 104 structured as described above as high-frequency power with, for instance, a frequency of 450 kHz is supplied from the high-frequency power source 118 to the coil 116. The processing gas delivered into the reaction container 140 becomes excited via the induction field thus generated, thereby generating plasma.

The side wall 142 constituted of an insulating material such as quartz glass, together with the coil 116 forms part of the high-frequency (RF) circuit at the reaction container 140 via which the induction field to be used to generate plasma inside the side wall 142 is formed. Unlike the side wall 142, the lid member 144, for instance, of the reaction container 140 does not constitute part of the high-frequency circuit. For this reason, while the side wall 142 must be constituted of an insulating member, the lid member 144 does not need to be constituted of an insulating member. Namely, the lid member 144 may be constituted of the same material as the side wall 142 or it may be constituted of a material different from that constituting the side wall. In addition, the lid member 144 may assume a thickness or a shape different from that of the side wall 142.

As plasma is generated inside the reaction container 140, ultraviolet light, which would react with the oxygen in the atmosphere to produce ozone, is generated from the plasma. Through testing and the like conducted by the inventor of the present invention et al., it has been confirmed that particularly intense ultraviolet light, far more so than the ultraviolet light originating from plasma generated by exciting an oxygen-containing processing gas, is generated from plasma generated by exciting a hydrogen-containing processing gas.

The side wall 142 at the reaction container 140 defines a vacuum inner space, the pressure in which is lowered to a predetermined degree of vacuum, separated from an outer space at atmospheric pressure. Thus, if the ultraviolet light originating from the plasma generated inside the side wall 142 is transmitted through the side wall 142 and leaks into the outer atmosphere, the ultraviolet light may react with oxygen in the atmosphere to produce ozone. The quantity of ozone produced through the reaction of the ultraviolet light originating from plasma generated by exciting such a hydrogen-containing processing gas, with the oxygen in the atmosphere was measured to be as much as approximately five times the quantity of ozone produced with ultraviolet light originating from plasma generated by exciting an oxygen-containing processing gas.

Accordingly, a film coating 150 that blocks ultraviolet light originating from plasma generated inside the reaction container 140 so as not to allow the ultraviolet light to leak to the outside is formed to cover the outer surface of the side wall 142 of the reaction container 140 at the plasma generation chamber 104 in the embodiment. The term “ultraviolet light” in this context refers to light emitted from plasma and having a shorter wavelength than visible light, which may react with the oxygen in the atmosphere to produce ozone. Such ultraviolet light may be vacuum ultraviolet light with an even shorter wavelength, as well as ultraviolet light in the atmosphere. In the embodiment, the ultraviolet light originating from the plasma is blocked at the film coating 150 and is thus prevented from leaking into the atmosphere further outside the side wall 142, thereby disallowing production of ozone outside the reaction container 140.

In addition, the film coating 150, which is formed between the side wall 142 and the coil 116 together constituting part of the high-frequency circuit at the reaction container 140, as described earlier, must adopt a structure that allows the overall high-frequency circuit to fulfill the functions of the high-frequency circuit as designed, as well as blocking the ultraviolet light.

In more specific terms, the film coating 150 should be constituted with a thin film formed by using an insulating material. The film coating 150, located further inside relative to the coil 116, must be constituted of an insulating material, since if the film coating 150 were constituted of an electrically conductive material, the high-frequency circuit at the reaction container 140 would become shorted as high-frequency power was applied to the coil 116, thereby disabling its functions. Even more specifically, while it is desirable that the film coating 150 achieve volume resistivity close to that of the insulating material constituting the side wall 142 of the reaction container 140, the volume resistivity of the film coating does not need to exactly match the volume resistivity of the side wall 142. For instance, it is desirable to use an insulating material with volume resistivity in the order of ≧10¹⁰ Ω·cm and it is even more desirable to use an insulating material with volume resistivity in the order of ≧10¹² Ω·cm to constitute the film coating.

In addition, by constituting the film coating 150 with a thin film formed through, for instance, CVD (chemical vapor deposition), the ultraviolet light can be blocked effectively without having to alter the thickness of the side wall 142 at the reaction container 140. It is desirable that the film coating 150 assume a thickness of approximately several μm in conjunction with a thickness of, for instance, several mm assumed at the side wall 142.

If the ultraviolet light were to be blocked simply by assuming a large thickness at the side wall 142 without disposing the film coating 150 at the side wall 142 of the reaction container 140, the thickness of the side wall 142, normally set at several mm, would have to be increased by a factor of 2 or more. However, as the thickness of the side wall 142 increased, the electrical characteristics of the high-frequency circuit at the reaction container 140, such as the capacitance, would be altered to a greater extent. There is another issue to be addressed in that as the thickness of the side wall 142 increased, the difference between the temperature at the inner surface of the side wall 142 and the temperature at the outer surface of the side wall 142 would also increase, which would result in a significant degree of internal stress, such as thermal stress, which could cause a breakdown of the side wall 142.

In contrast, while the film coating 150 coats the side wall 142 in the embodiment, the thickness of the side wall 142 remains unchanged, allowing the electrical characteristics of the high-frequency circuit at the reaction container 140, such as its capacitance, to remain unaltered. This makes it possible to generate the desired induction field. Consequently, desired wafer processing results can be obtained, since the state of the plasma generated by using the induction field, e.g., the plasma generation position, the plasma density along the in-plane direction and the plasma intensity) does not change, either.

In addition, the film coating 150, which blocks the ultraviolet light in the embodiment, can be deposited without any air gap over the entire outer surface of the side wall 142 through, for instance, CVD (chemical vapor deposition). The absence of air between the side wall 142 and the film coating 150, assured through these measures, prevents production of ozone between the side wall 142 and the film coating 150.

However, the film coating 150 covering the side wall 142 of the reaction container 140 must have enough heat resisting performance to withstand the high temperature at the outer surface of the side wall 142. The temperature at the outer surface of the side wall 142 rises to a higher level (e.g., 400° C. or higher) as the high-frequency power supplied to the coil 116 increases. More specifically, while the temperature increase at the outer surface of the side wall 142 is affected by the material constituting the side wall and the thickness of the side wall, the temperature is likely to rise to approximately 400° C. if the high-frequency power is approximately 3 kW and is likely to rise to 500° C.˜600° C. if the high-frequency power is approximately 5 kW. Accordingly, the film coating 150 should achieve enough heat resisting performance to withstand temperatures of 400° C. and higher in practical application.

In addition, it is desirable that the film coating 150 covering the side wall 142 assume a coefficient of thermal expansion as close as possible to the coefficient of thermal expansion of the side wall 142. Since the outer surface of the side wall 142 is heated to 400° C. or higher, a significant difference between the coefficients of thermal expansion of the film coating 150 and the side wall 142 will result in a significant difference between the extent to which the side wall 142 thermally expands and the extent to which the film coating 150 thermally expands along the vertical direction. When they thermally expand to significantly different extents, a more significant degree of internal stress occurs between the side wall 142 and the film coating 150, to readily induce cracking at the side wall 142 or the film coating 150. For this reason, the coefficient of thermal expansion of the film coating 150 should be set as close as possible to the coefficient of thermal expansion of the side wall 142.

However, under certain temperature conditions (e.g., the temperature level and the pattern with which the temperature changes repeatedly) at the outer surface of the side wall 142, even a significant difference between the coefficients of thermal expansion at the film coating 150 and the side wall 142 does not cause cracking. In other words, depending upon operating conditions, the acceptable range of the difference between the coefficients of thermal expansion at the film coating 150 and the side wall may widen. In addition, as long as the side wall 142 and the film coating 150 are set in complete contact with each other, even a difference between the coefficients of thermal expansion of the film coating 150 and the side wall 142 does not cause cracking and the like at the side wall 142 or the film coating 150. The level of adhesion with which the film coating 150 contacts the side wall 142 can be increased specifically by forming the film coating 150 through, for instance, CVD at the side wall 142 in the embodiment. Through these measures, the occurrence of cracking and the like at the side wall 142 or the film coating 150 can be prevented to a full extent even if there is some difference between the coefficients of thermal expansion at the film coating 150 and the coefficients of thermal expansion at the side wall 142 (e.g., a difference in the order of 10²/° C.˜10³/° C.).

As described above, while it is desirable that the coefficients of thermal expansion of the film coating 150 and the side wall 142 be as close as possible, they do not necessarily have to exactly match. In other words, the material constituting the film coating 150 simply needs to assume a coefficient of thermal expansion at which the extent of thermal expansion of the film coating 150 does not greatly differ from the extent of thermal expansion of the side wall 142. For instance, if the side wall 142 is constituted of quartz glass (with the coefficient of thermal expansion thereof in the order of 10^{31 8}/° C.), the coefficient of thermal expansion of the film coating 150 should in the order of 10⁻⁶/° C.˜10⁻⁵/° C. or less.

Such a film coating 150 in the embodiment may be, for instance, a silica-containing amorphous carbon film. A silica-containing amorphous carbon film material assures a high level of ultraviolet light blocking property, which does not allow transmission of light with wavelengths equal to and less than 300 nm, including ultraviolet light. The silica-containing amorphous carbon film material is an insulating material with its volume resistivity in the order of 10¹² Ω·cm and a heat resisting property that allows it to withstand high temperatures of 500° C. and higher. By using such a silica-containing amorphous carbon film material, a thin film can be formed at the side wall 142 through CVD.

It will be obvious that the film coating 150 in the embodiment may be formed by using a material other than the silica-containing amorphous carbon film material. An optimal material, with which a thin film with an insulating property and a heat resisting property such as those described above can be formed, should be used to constitute the film coating 150, depending upon the temperature conditions at the side wall 142, the level of the high-frequency power applied to the coil 116 and the wavelength of the ultraviolet light originating from the plasma. For instance, under circumstances in which ultraviolet light having a wavelength equal to or less than 200 um is generated from the plasma and would produce ozone if transmitted through the side wall 142, a thin film that blocks ultraviolet light in this wavelength range, e.g., a dense Y₂O₃ film, may be formed at the outer surface of the side wall 142 as the film coating 150.

In addition, the film coating 150 does not need to be formed over the outer surfaces of the upper flange 142a and the lower flange 142b at the side wall 142 at the reaction container 140. The ultraviolet light originating from the plasma does not readily reach the areas where the upper flange 142a and a lower flange 142b are present, and also, the upper flange 142a and the lower flange 142b are normally thicker than the area in between (the side portion of the side wall 142). This means that even if ultraviolet light reaches the areas where the upper flange 142a and the lower flange 142b are present, the ultraviolet light is bound to have greatly dissipated by the time it reaches the outer side of the flanges and thus, the ultraviolet light does not leak out through the upper flange 142a and the lower flange 142b.

For this reason, it suffices to form the film coating 150 only over the area of the outer surface of the side wall ranging between the upper flange 142a and the lower flange 142b, as shown in FIG. 1. However, if the upper flange 142a and the lower flange 142b assume a smaller thickness, the film coating 150 may also be formed over the outer surfaces of the upper flange 142a and the lower flange 142b. It is to be noted also that the presence of the upper flange 142a and the lower flange 142b at the side wall 142 of the reaction container 140 is not an essential structural requirement.

A wafer W to be processed with hydrogen radicals in the plasma processing apparatus 100 structured as described above is first carried into the processing chamber 102 through the transfer port 132 by opening the gate valve 130.

Subsequently, the gate valve 130 is closed and the processing chamber 102 and the plasma generation chamber 104 are evacuated by the exhaust device 127 until the pressure inside is reduced to a predetermined low level. In addition, the level of power to be supplied from the heater power source 114 to the heater 112 is selected so as to heat the wafer W to a predetermined temperature (e.g., 300° C.).

Then, high-frequency power (e.g., 4000 W) is supplied to the coil 116 from the high-frequency power source 118 while supplying the processing gas constituted with a hydrogen-containing gas from the gas supply source 120 into the plasma generation chamber 104 via the gas delivery port 122, thereby forming an induction field inside the plasma generation chamber 104 and consequently generating hydrogen plasma inside the plasma generation chamber 104. A specific type of processing such as ashing of the photoresist film present on the surface of the wafer W is executed on the surface of the wafer W placed inside the processing chamber 102 with the hydrogen plasma generated inside the reaction container 140 as described above.

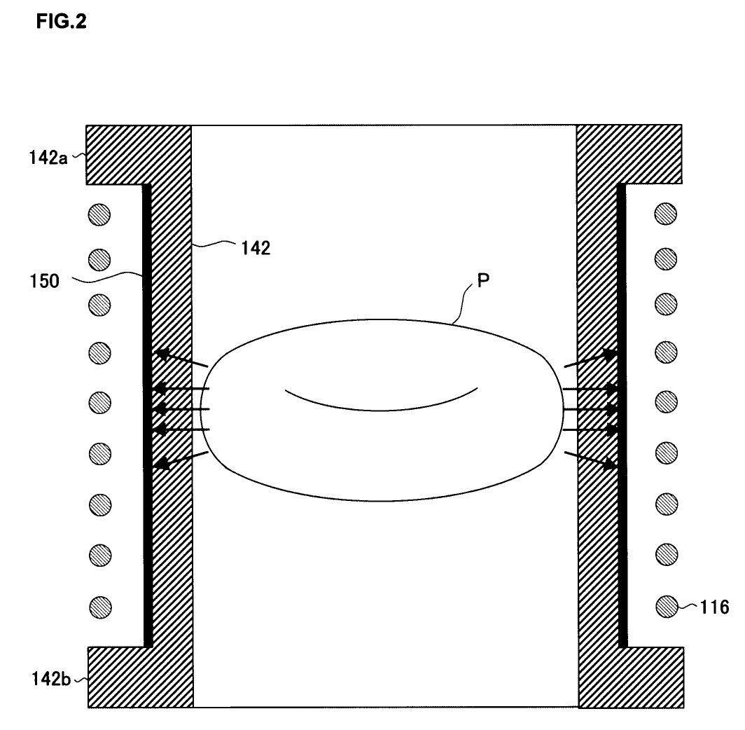

While ultraviolet light (indicated by the arrows in FIG. 2) originating from the plasma P generated in the plasma generation chamber 104 irradiates the side wall 142 of the reaction container 140, the ultraviolet light is blocked at the film coating 150 and is thus not allowed to further advance to leak into the atmosphere outside the side wall 142, as shown in FIG. 2. As a result, ozone production outside the side wall 142 is prevented.

### (Test Results)

The results of tests conducted to confirm the ozone production preventing effect by using the plasma processing apparatus 100 achieved in the embodiment are now described. Table 1 below presents the results of tests conducted to compare the ozone production preventing effect achieved in conjunction with the film coating 150 constituted of a silica-containing amorphous carbon film material and formed at the side wall 142 of the reaction container 140 (film coating present) with the ozone production preventing effect achieved without the film coating 150 (film coating absent). The test processing was executed under the following conditions. Namely, a mixed gas containing hydrogen gas and an inert gas with the hydrogen gas mixed at a ratio of 4% was used as the processing gas. The pressure inside the processing chamber was set to 1.5 Torr and the level of the high-frequency power applied to the coil 116 was adjusted to 3 kW. Under these processing conditions, the plasma processing apparatus 100 was engaged in operation with the film coating 150 formed at the side wall 142 and also without the film coating 150 at the side wall 142, and the quantities of ozone present outside the side wall 142 were measured before and after the operation.

It is to be noted that in the tests, the quantities of ozone were measured at a position corresponding to an area inside the reaction container 140 where plasma would be generated with the highest intensity, e.g., at a position outside the side wall 142 near the center of the plasma generation chamber 104 in FIG. 1 along the height-wise direction. In addition, the ozone quantities were measured by allowing a thirty-second interval after applying the high-frequency power to the coil 116. The timing of the ozone quantity measurement was set as described above based upon the following rationale. Namely, the quantity of ozone generated with ultraviolet light originating from plasma peaks as the plasma stabilizes following the start of the high-frequency power application to the coil 116 (e.g., 30 to 60 seconds after the start of the high-frequency power application) and subsequently, the quantity of ozone gradually decreases, as confirmed through other tests. Accordingly, the quantity of ozone was measured with the timing with which the ozone quantity was likely to peak (30 seconds after the start of high-frequency power application in this example).

TABLE 1

| | FILM COATING | FILM COATING |
|---|---|---|
| | ABSENT | PRESENT |
| PRE-OPERATION | 0.012 | 0.012 |
| OZONE QUANTITY | | |
| (ppm) | | |
| POST-OPERATION | 0.570 | 0.012 |
| OZONE QUANTITY | | |
| (ppm) | | |

The results presented in Table 1 above indicate that compared to the pre-operation ozone quantity (background ozone quantity) of 0.012 ppm measured before the plasma generation, the post-operation ozone quantity measured after the plasma generation increased by a significant extent to 0.570 ppm with no film coating 150 formed at the side wall (film coating absent). The significant increase in the ozone quantity is assumed to be attributable to the ultraviolet light from the plasma leaking to the outside through the side wall 142 and producing ozone through a reaction with oxygen in the atmosphere.

In contrast, no change from the pre-operation ozone quantity of 0.012 ppm occurred when the film coating 150 was present at the side wall (film coating present). These test results indicate that the presence of the film coating 150 formed at the side wall (film coating present) prevents leakage of ultraviolet light originating from the plasma P to the outside of the side wall 140 and thus prevents ozone production, as the ultraviolet light is blocked at the film coating 150 as shown in FIG. 2.

Table 2 below presents the results of tests conducted by engaging the plasma processing apparatus 100 in operation under processing conditions similar to those described above and adjusting the level of the high-frequency power applied to the coil 116. In the tests, the plasma processing apparatus 100, with the film coating 150 constituted of a silica-containing amorphous carbon film material and formed at the side wall 142 of the reaction container 140 (film coating present), was engaged in operation by setting the level of the high-frequency power applied to the coil 116 to 1.5 kW, 4 kW and 5 kW, and the quantities of ozone were measured in the pre-operation state and in the post-operation state as explained earlier.

TABLE 2

| | FILM COATING | | |
|---|---|---|---|
| | PRESENT | | |
| HIGH-FREQUENCY | 1.5 | 4 | 5 |
| POWER | | | |
| (kW) | | | |
| PRE-OPERATION | 0.014 | 0.014 | 0.020 |
| OZONE QUANTITY | | | |
| (ppm) | | | |
| POST-OPERATION | 0.014 | 0.016 | 0.020 |
| OZONE QUANTITY | | | |
| (ppm) | | | |

The test results presented in Table 2 indicate that hardly any change occurred in the post-operation ozone quantity relative to the pre-operation ozone quantity, regardless of the level of the high-frequency power applied to the coil 116 was 1.5 kW, 4 kW or 5 kW. This means that as long as the film coating 150 is present at the side wall (film coating present), the ultraviolet light generated from plasma is bound to be blocked at the film coating 150 to disallow ultraviolet light leakage to the outside of the side wall 142 and ultimately prevent ozone production, regardless of the level of the high-frequency power applied to the coil 116.

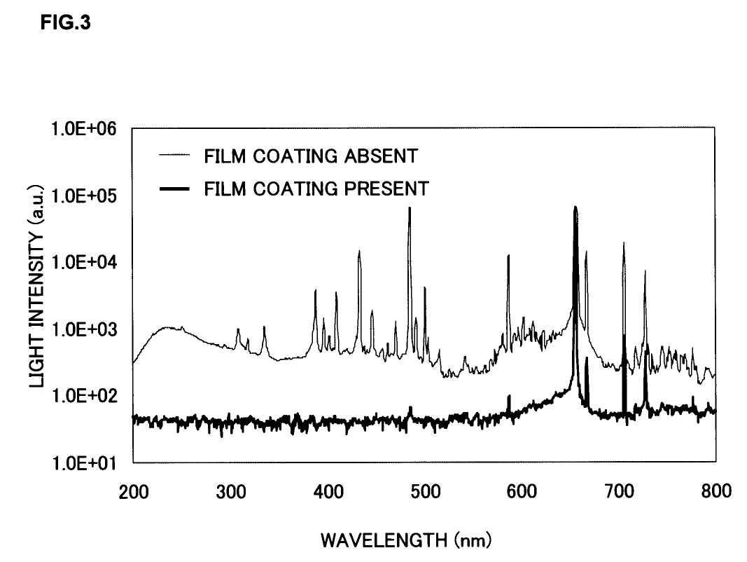

The results of tests conducted in order to confirm that the ultraviolet light originating from plasma was actually blocked are now described. In the tests, the spectrum (200 nm˜800 nm) of the light received outside the side wall 142 was measured by assuming a 1.5 kW˜5 kW high-frequency power range with regard to the level of the high-frequency power applied to the coil 116 and a 3 L˜9 L range for the flow rate of the processing gas constituted with an inert gas with a hydrogen gas content at 4%. The measurement was taken in correspondence to each of various combinations of the high-frequency power level/processing gas flow rate within these ranges, with (film coating present) and without (film coating absent) the film coating 150 constituted of a silica-containing amorphous carbon film material formed at the side wall. All the test results confirmed that the ultraviolet light was blocked at the film coating to a sufficient extent so as to inhibit ozone production. Since similar ultraviolet blocking effects were observed through all the tests, the results of tests conducted by setting the high-frequency power applied to the coil 116 to 1.5 kW and the processing gas flow rate to 3 L are presented in FIG. 3 as a typical example.

The test results presented in FIG. 3 indicate that while the overall intensity increased over the ultraviolet light wavelength range (e.g., the wavelength range of 400 nm and shorter) and the peak intensity, too, increased at certain wavelengths when no film coating 150 was formed (film coating absent), the overall intensity was lowered and no peak in the intensity was observed when the film coating 150 was formed (film coating present). This means that ultraviolet light, which is bound to induce ozone generation, can be blocked and thus prevented from leaking to the outside of the side wall 142 more effectively in a plasma processing apparatus with the film coating 150 formed thereat (film coating present), compared to in a plasma processing apparatus with no such film coating 150 (film coating absent).

As plasma is generated during wafer processing, the temperature at the side wall 142 rises (e.g., to 400° C. or higher). Once the wafer processing ends, the plasma dissipates and thus, the temperature of the side wall 142 falls to the normal range (e.g., 25° C.). As the wafer processing is executed repeatedly, the side wall 142 repeatedly undergoes the high/low temperature cycle during which the film coating 150 at the side wall 142 repeatedly becomes thermally expanded as the temperature changes. As the high/low temperature cycle is repeated over a greater number of times and as the wafer W is processed at the temperature with a greater difference relative to the temperature assumed in the non-processing state, the strength of the film coating 150 is lowered to a greater extent to readily cause cracking. In particular, if the coefficient of thermal expansion of the film coating 150 is different from the coefficient of thermal expansion of the side wall 142, stress corresponding to the difference between the extents to which the film coating 150 and the side wall 142 expand occurs, and the strength of the film coating 150 is bound to be compromised.

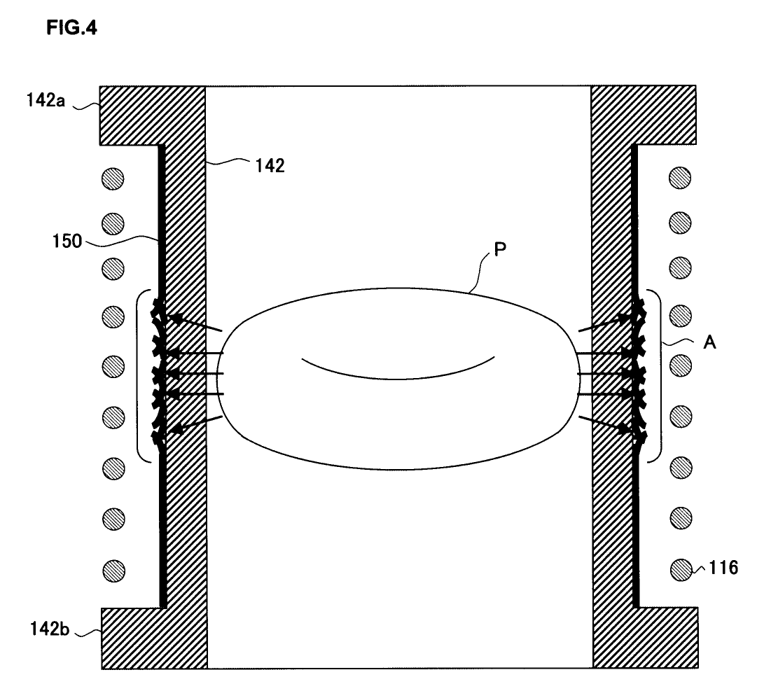

Under these circumstances, if the coefficient of thermal expansion of the film coating 150 is greater than the coefficient of thermal expansion of the side wall 142, for instance, the film coating 150 will stretch to a greater extent, as shown in FIG. 4. Thus, if the film coating 150 becomes cracked, the cracked areas are bound to become overlapped with each other. Furthermore, the film coating 150 tends to become cracked readily over an area closer to the position at which the plasma P is generated with the highest intensity, as over an area A in FIG. 4, presumably because intense light including the ultraviolet light originating from the plasma P tends to concentrate more readily over an area closer to the plasma P.

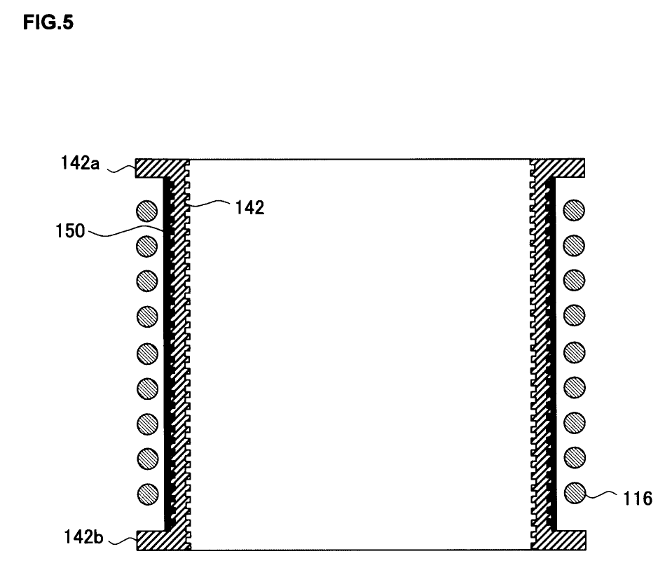

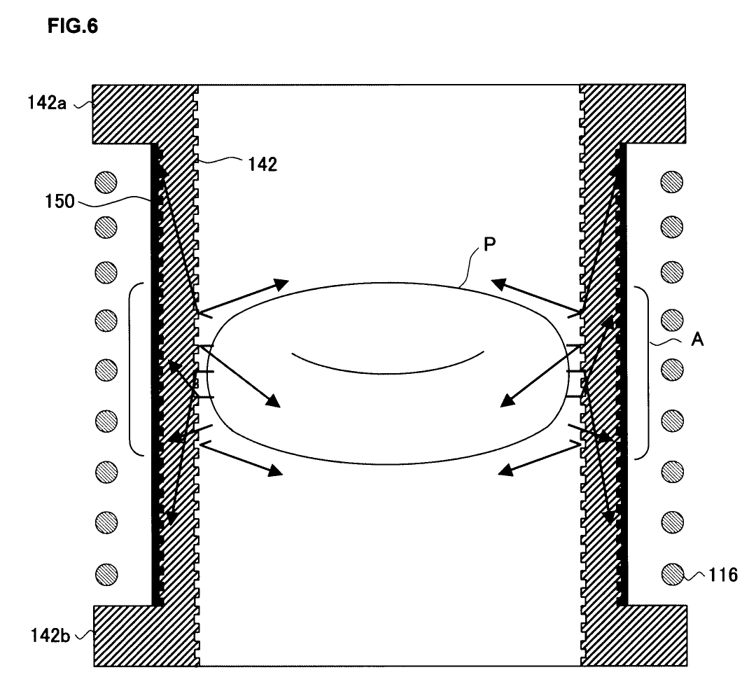

Accordingly, cracking at the film coating 150 due to lowered strength thereof may be prevented by roughening the entire inner surface and the entire outer surface of the side wall 142 of the reaction container 140 and forming the film coating 150 at the roughened outer surface, as shown in FIG. 5. Light including the ultraviolet light originating from the plasma P can be randomly reflected at the inner surface and the outer surface of the side wall 142 having undergone the roughening treatment, as shown in FIG. 6 and, as a result, the light is not allowed to concentrate over any specific area of the side wall 142 (e.g., the area A in FIG. 6). In addition, since the film coating 150 is formed at the outer surface of the side wall 142 having undergone the roughening treatment, the level of adhesion with which the side wall 142 and the film coating 150 contact each other is improved, to effectively prevent cracking at the film coating 150.

It is to be noted that while FIG. 5 presents a specific example in which the entire outer surface at which the film coating 150 is formed is roughened and the inner surface of the side wall 142, too, is roughened in its entirety, the present invention is not limited to this example and only part of the inner surface of the side wall 142 may be roughened. In such a case, it is desirable to roughen a specific area of the inner surface of the side wall 142 that surrounds the plasma, in correspondence to the position at which the plasma is generated inside the reaction container 140. For instance, if plasma is generated over the central area along the height of the side wall 142, as shown in FIG. 6, the inner surface of the side wall 142 should be roughened specifically over the central area surrounding the plasma.

Through these measures, the area of the inner surface of the side wall 142, where intense light including the ultraviolet light originating from plasma tends to concentrate and thus cracking of the film coating 150 is likely to occur is roughened to induce irregular reflection. In this case, the area of the inner surface of the side wall 142 to undergo the roughening treatment can be minimized while effectively preventing cracking of the film coating 150. Consequently, adhesion of particles and the like of reaction products to the inner surface of the side wall 142 can be minimized.

It is to be noted that if a plurality of plasma formations are induced along the height of the reaction container 140, the inner surface of the side wall 142 may be roughened over various areas surrounding the individual plasma formations or the inner surface of the side wall 142 may be roughened only over the area surrounding the space where plasma is generated with the highest intensity. For instance, if a total of three toroidal plasma formations, set apart from each other and assuming positions at the center along the height of the reaction container 140 and above and below the center, are induced as described earlier, the plasma will be generated with the highest level of intensity at the center and, accordingly, the inner surface of the side wall 142 should be roughened over the central area corresponding to the center of the reaction container 140 assumed along its height so as to surround the high-intensity plasma.

In addition, while the inner surface of the side wall 142 may be only partially roughened as described above, it is desirable to roughen the entire outer surface of the side wall 142, since the adhesion of particles and or the like does not occur at the outer surface of the side wall 142 and the film coating 150 can be deposited with better contact at the outer surface of the side wall 142 by roughening the outer surface over its entirety.

Furthermore, cracking of the film coating 150 due to lower strength can be prevented by assuming a multilayer structure at the side wall 142 of the reaction container 140 so as to keep down the temperature at the outer surface of the side wall 142 as plasma is generated inside the reaction container 140. For instance, the side wall 142 may be formed as an integrated unit with a plurality of tubular members constituted of an insulating material layer one on top of another, with a vacuum sealed space present therebetween and the film coating 150 may be formed at the outermost surface of the side wall 142.

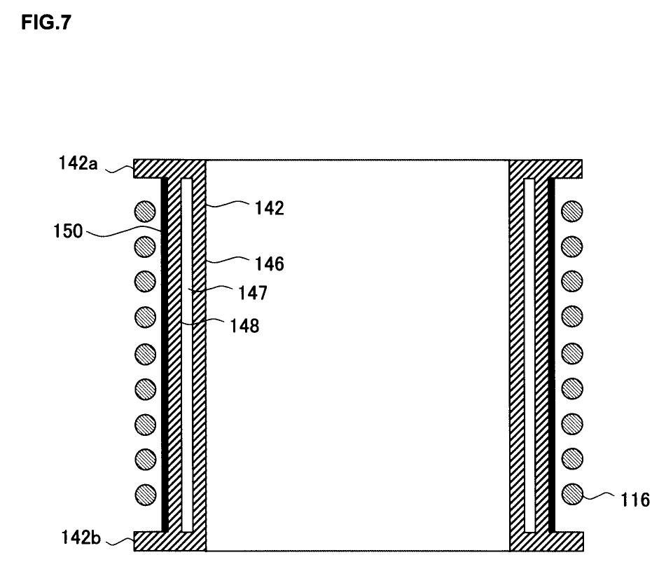

FIG. 7 presents a specific example of a reaction container 140 with its side wall 142 assuming a double-layer structure. The side wall 142 shown in FIG. 7 is an integrated wall formed by layering two tubular members 146 and 148 constituted of an insulating material one on top of the other with a vacuum sealed space 147 present therebetween. The film coating 150 is formed at the outer surface of the outermost tubular member 148 constituting the side wall 142.

Even as light including the ultraviolet light originating from the plasma generated inside the reaction container 140 structured as described above is radiated onto the side wall, the light is greatly attenuated while it travels through the inner tubular member 146, the vacuum sealed space 147 and the outer tubular member 148 and thus, the temperature at the outer surface of the side wall 142 can be kept lower than the temperature at the outer surface of a side wall 142 with a single-layer structure. Furthermore, a better adiabatic effect is achieved with the vacuum sealed space 147 present between the tubular members 146 and 148, so as to further keep down the temperature at the outer surface of the side wall 142. As a result, the difference between the temperature at the outer surface of the side wall 142 when the plasma is generated inside the reaction container and the temperature at the outer surface when no plasma is generated can be minimized, which further prevents cracking at the film coating 150. Furthermore, since the temperature at the outer surface of the side wall 142 where the film coating 150 is deposited is lowered, the film coating 150 does not need to be formed with a material having a very high level of heat resisting performance.

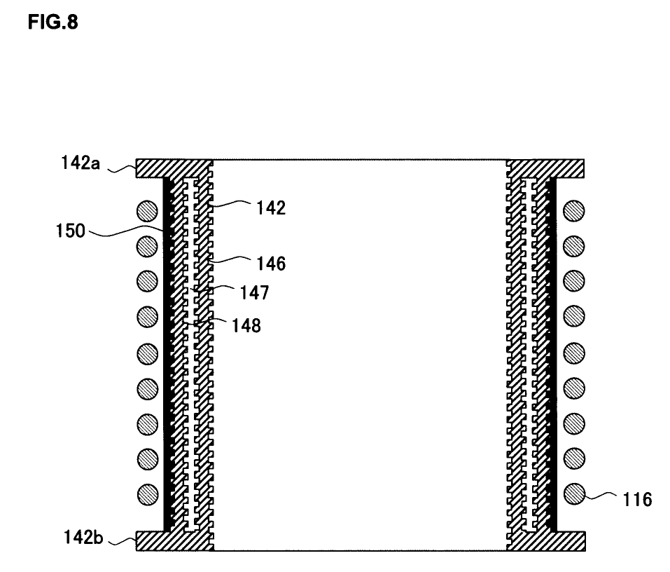

It is to be noted that the inner surfaces and the outer surfaces of the individual tubular members constituting the side wall 142 assuming a multilayer structure may be roughened. Through these measures, a concentration of light including the ultraviolet light originating from the plasma P over a specific area of the side wall 142 can be prevented. For instance, FIG. 8 shows the side wall 142 with the double-layer structure in FIG. 7 with the inner surfaces and the outer surfaces of the individual tubular members 146 and 148 having undergone a roughening treatment. In this case, light including the ultraviolet light originating from the plasma can be irregularly reflected at the inner surfaces and the outer surfaces of both tubular members 146 and 148 so as to further improve the effect with which cracking of the film coating 150 is prevented.

While the invention has been particularly shown and described with respect to preferred embodiment thereof by referring to the attached drawings, the present invention is not limited to this example and it will be understood by those skilled in the art that various changes in form and detail may be made therein without departing from the spirit, scope and teaching of the invention.

What is claimed is:

1. A plasma processing apparatus that executes a specific type of processing on a processing target substrate with plasma generated by exciting a hydrogen-containing processing gas, comprising:
a plasma generation chamber where plasma is generated by exciting the processing gas;
a processing chamber communicating with said plasma generation chamber; and
a stage disposed inside said processing chamber, upon which the processing target substrate is placed, wherein:
said plasma generation chamber includes;
a reaction container having a tubular side wall;
a processing gas delivery unit through which said processing gas is delivered into said reaction container;
a coil wound around said side wall, to which specific high-frequency power is applied and a film coating that covers the outer surface of said side wall; and
said film coating is a thin film constituted of an insulating material with a heat resisting property, which blocks ultraviolet light originating from the plasma generated inside said reaction container.

2. A plasma processing apparatus according to claim 1, wherein:
said film coating achieves a heat resisting property to withstand high temperatures of at least 400° C. and higher.

3. A plasma processing apparatus according to claim 1, wherein:
said film coating is constituted of a silica-containing amorphous carbon film material.

4. A plasma processing apparatus according to claim 1, wherein:
the inner surface and the outer surface of said side wall of said reaction container are roughened and said film coating is formed at the roughened outer surface of said side wall.

5. A plasma processing apparatus according to claim 4, wherein:
the inner surface and the outer surface of said side wall of said reaction container are roughened over the entirety thereof.

6. A plasma processing apparatus according to claim 4, wherein:
the outer surface of said side wall of said reaction container is roughened over the entirety thereof and the inner surface of said side wall is partially roughened.

7. A plasma processing apparatus according to claim 4, wherein:
the inner surface of said side wall of said reaction container is roughened over a specific area surrounding plasma generated inside said reaction container based upon a plasma generation position inside said reaction container.

8. A plasma processing apparatus that executes a specific type of processing on a processing target substrate with plasma generated by exciting a hydrogen-containing processing gas, comprising:
a plasma generation chamber where plasma is generated by exciting the processing gas;
a processing chamber communicating with said plasma generation chamber; and
a stage disposed inside said processing chamber, upon which the processing target substrate is placed, wherein:
said plasma generation chamber in said plasma processing apparatus includes:
a reaction container having a side wall formed as an integrated member by layering a plurality of tubular members constituted of an insulating material with a vacuum sealed space set therebetween;
a processing gas delivery unit through which said processing gas is delivered into said reaction container;
a coil wound around said side wall, to which specific high-frequency power is applied; and
a film coating that covers the outer surface of said side wall;
said film coating is a thin-film constituted of an insulating material with a heat resisting property, which blocks ultraviolet light originating from the plasma generated inside said reaction container.

9. A plasma processing apparatus according to claim 8, wherein:
said film coating achieves a heat resisting property to withstand high temperatures of at least 400° C. and higher.

10. A plasma processing apparatus according to claim 8, wherein:
said film coating is constituted of a silica-containing amorphous carbon film material.

11. A plasma processing apparatus according to claim 8, wherein:
the inner surfaces and the outer surfaces of said tubular members are roughened and said film coating is formed at the roughened outer surface of a tubular member disposed at an outermost position.

12. A plasma generation chamber where plasma is generated by exciting a hydrogen-containing processing gas, comprising:
a processing gas intake portion via said processing gas is taken in;
a reaction container having a tubular side wall;
a processing gas delivery unit through which said processing gas is delivered into said reaction container;
a coil wound around said side wall, to which specific high-frequency power is applied; and
a film coating that covers the outer surface of said side wall, wherein:
said film coating is a thin film constituted of an insulating material with a heat resisting property, which blocks ultraviolet light originating from the plasma generated inside said reaction container.
